(19) United States
(12) Patent Application Publication
(10) Pub. No.: US 2016/0049904 A1
(43) Pub. Date: Feb. 18, 2016

(54) SOLAR CELL MODULE AND SOLAR CELL PANEL

(71) Applicant: Dai Nippon Printing Co., Ltd., Tokyo (JP)

(72) Inventor: MIHO SASAKI, TOKYO (JP)

(21) Appl. No.: 14/458,281

(22) Filed: Aug. 13, 2014

(51) Int. Cl. H02S 99/00; H01L 31/042

(52) U.S. Cl. CPC H02S 99/00; H01L 31/042

(57) ABSTRACT

A solar cell module comprises: two or more solar cell elements provided at intervals; a first colored layer provided between adjacent solar cell elements; and a diffusion layer and a second colored layer provided, on a side of a light receiving surface of the solar cell module, directly or through another layer in this order from the solar cell element side. A difference in luminance between a color of a region above the solar cell element and a color of a region above a gap between adjacent solar cell elements, in an anterior view of a surface of the diffusion layer of the solar cell module with the second colored layer removed, is up to 2.3.

### TECHNICAL FIELD

The present invention relates to a solar cell module and a solar cell panel.

### BACKGROUND OF THE INVENTION

There have currently been developed efforts to limit emission of CO₂ on a worldwide scale, as a measure to prevent global warming. A solar cell module in which a plurality of solar cells are electrically connected to each other, and a solar cell panel in which a plurality of such solar cell modules are electrically connected to each other, have attracted public attention as a clean power-generating equipment, and research and development regarding them have been carried out.

In addition, the solar cell modules or the solar cell panels have recently been mounted not only on various kinds of outdoor articles, but also on various kinds of and articles for utilization of them. However, they have sometimes caused a problem of designability. Therefore, there is a demand to provide the whole light receiving surface of the solar cell modules or the solar cell panels with a desired designability.

With respect to a technical measure to provide a light receiving surface of a solar cell module with designability, there are technical measures disclosed for example in Patent Document 1 and Patent Document 2.

### PRIOR ART DOCUMENT

### Patent Document

[Patent Document 1] Japanese Patent Provisional Publication No. H11-298026
[Patent Document 2] Publication of Japanese Patent No. 5206899
[Patent Document 3] Japanese Patent Provisional Publication No. 2011-210861

### DISCLOSURE OF THE INVENTION

### Subject to be Solved by the Invention

Patent Document 1 and Patent Document 2 disclose a technical measure to provide designability by forming a diffusion layer on a side of a light receiving surface of a solar cell module to diffuse light by such a diffusion layer so as to whiten the whole light receiving surface.

Patent Document 3 discloses a technical measure to provide a light receiving surface of a solar cell module with designability by coloring a filler material on a non-light receiving surface, for forming the solar cell module, to provide a color between adjacent solar cell elements.

However, such technical measures merely provide designability to the extent of whitening evenly the light receiving surface of the solar cell module or the solar cell panel, or making a gap between the adjacent solar cell elements less noticeable, or, lacing the light receiving surface of the solar cell module, thus leading to difficulty in providing the light receiving surface with a high grade designability such as a desired motif or characters.

A main object of the present invention, which has been made under recognition of such an actual situation, is to provide a solar cell module and a solar cell panel, which have been expected as a measure to prevent global warming, and is provided on their light receiving surface with a high grade designability.

### Means to Solve the Subject

The solar cell module of the present invention to solve the above-mentioned subject comprises: two or more solar cell elements provided at intervals; a first colored layer provided between adjacent solar cell elements; and a diffusion layer and a second colored layer provided, on a side of a light receiving surface of the solar cell module, directly or through another layer in this order from the solar cell element side, wherein: a difference in luminance between a color of a region above the solar cell element and a color of a region above a gap between adjacent solar cell elements, in an anterior view of a surface of the diffusion layer of the solar cell module with the second colored layer removed, is up to 2.3.

In the present invention as described above, the second colored layer may be provided in a form of dots.

In the present invention as described above, a transparent layer may be provided between the diffusion layer and the second colored layer.

In the present invention as described above, a color difference ΔE between the color of the region above the solar cell element and the color of the region above the gap between the adjacent solar cell elements, in an anterior view of the surface of the diffusion layer of the solar cell module with the second colored layer removed, may be up to 15.0.

In the present invention as described above, a protective layer may be provided on the second colored layer.

The solar cell panel of the other present invention to solve the above-mentioned subject comprises: two or more solar cell modules provided at intervals, each of the solar cell modules comprising two or more solar cell elements provided at intervals; a first colored layer provided between adjacent solar cell elements of the solar cell module and between adjacent solar cell modules; and a diffusion layer and a second colored layer provided, on a side of a light receiving surface of the solar cell panel, directly or through another layer in this order from the solar cell element side, wherein: a difference in luminance between a color of a region above the solar cell element and a color of regions above a gap between the adjacent solar cell elements and a gap between the adjacent solar cell modules, in an anterior view of a surface of the diffusion layer of the solar cell panel with the second colored layer removed, is up to 2.3.

The solar cell panel of the further other present invention to solve the above-mentioned subject comprises: two or more solar cell modules provided at intervals, each of the solar cell modules comprising two or more solar cell elements; a first colored layer provided between adjacent solar cell modules; and a diffusion layer and a second colored layer provided, on a side of a light receiving surface of the solar cell panel, directly or through another layer in this order from the solar cell element side, wherein: a difference in luminance between a color of a region above the solar cell element and a color of a region above a gap between the adjacent solar cell modules, in an anterior view of a surface of the diffusion layer of the solar cell panel with the second colored layer removed, is up to 2.3.

### Technical Effects of the Invention

According to the solar cell module of the present invention, the first colored layer is provided between the adjacent solar cell elements, on the one hand, and the diffusion layer is provided on the side of the light receiving surface, on the other hand, such first colored layer and diffusion layer provide the difference in luminance between the color of the region above the solar cell element and the color of the region above the gap between the adjacent solar cell elements being up to 2.3. It is therefore possible to keep a so-called underlayer prior to the formation of the second colored layer in a clear state in which a color unevenness may not be highly visible, and form the second colored layer above such an underlayer, thus facilitating a coloring function of the second colored layer and providing it with a high grade designability. In addition, the second colored layer can be formed above the clear underlayer in which the color unevenness may not be highly visible, as described above, with the result the second colored layer itself may not necessarily be formed across the light receiving surface, and it may be provided in the form of motif or characters, thus permitting to enlarge the range of choice of the designability.

Alternatively, according to the solar cell panel of the present invention, the first colored layer is formed between the adjacent solar cell modules, thus making it possible to control the color unevenness caused between the adjacent solar cell modules.

### BRIEF DESCRIPTION OF THE DRAWINGS

FIG. 1 is a cross-sectional view of the solar cell module according to the first embodiment of the present invention;

FIG. 2 is a cross-sectional view of the solar cell module according to the second embodiment of the present invention;

FIG. 3 is a cross-sectional view of the solar cell module according to the third embodiment of the present invention;

FIG. 4 is a schematic cross-sectional view of the solar cell panel according to the fourth embodiment of the present invention; and

FIG. 5 is a schematic cross-sectional view of the solar cell panel according to the fifth embodiment of the present invention.

### EMBODIMENTS FOR CARRYING OUT THE INVENTION

Now, embodiments of the present invention will be described in detail below with reference to the accompanying drawings.

The present invention is not limited only to the embodiments as described above, and various alternatives to the embodiments may be employed in practicing the present invention without departing from its technical concept. The accompanying drawings may show exaggerated scale sizes to facilitate understanding in vertical and horizontal directions and a scale size in the drawings may differ from the actual object.

### First Embodiment of the Present Invention

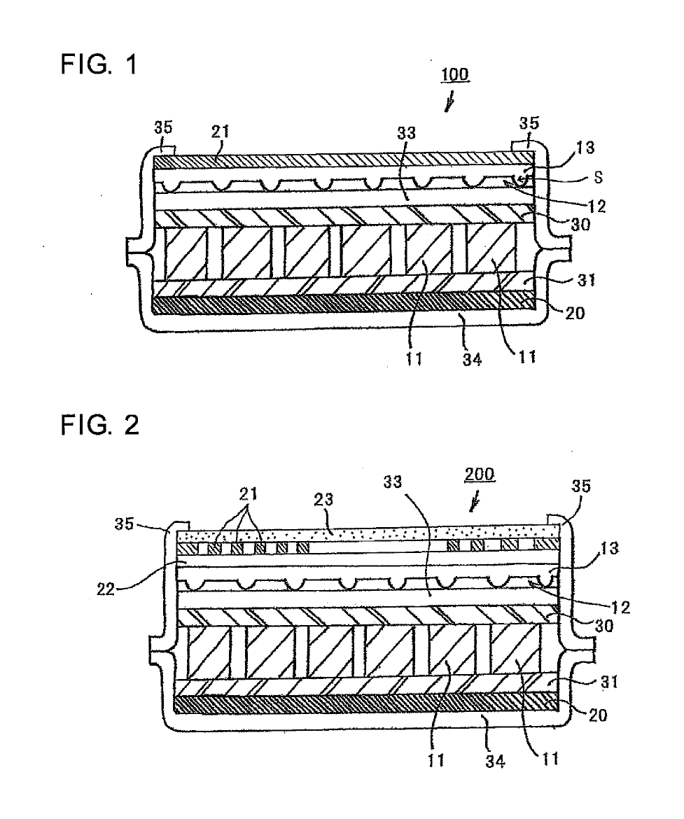

FIG. 1 is a schematic cross-sectional view of the solar cell module according to the first embodiment of the present invention.

The solar cell module 100 according to this embodiment includes two or more solar cell elements 11, 11 . . . placed at intervals; a light receiving surface side thermoplastic resin layer 30 and a back surface side thermoplastic resin layer 31 between which these solar cell elements 11, 11 . . . are held; a polyethylene terephthalate resin layer placed on the light receiving surface side thermoplastic resin layer 30; a back sheet 34 placed on the back surface of the solar cell module 100; and a sealing material 35 placed at the edge of the light receiving surface of the solar cell module 100, and a first colored layer 20 is provided between the back sheet 34 and the back surface side thermoplastic resin layer 31; and further a diffusion layer 13 is provided on the side of the light receiving surface. In this state, a difference in luminance between a color of a region above the solar cell element 11 and a color of a region above a gap between adjacent solar cell elements, in an anterior view of the light receiving surface, is up to 2.3. A second colored layer 21 is provided directly on the diffusion layer 13. Finally, the above-mentioned back sheet 34 and the sealing material 35 are thermal-fusion bonded to each other so that all the components are combined in a united body.

According to such a solar cell module 100, the first colored layer 20 is provided between the solar cell element 11 and the adjacent solar cell element 11, when viewing the surface of the diffusion layer of the solar cell module with the second colored layer removed, and it is possible to make the gap between the adjacent solar cell elements not highly visible. In addition, the diffusion layer 13 is provided on the side of the light receiving surface, thus permitting to diffuse light in an appropriate manner by such a diffusion layer 13, and it is therefore possible to keep the whole surface of the diffusion layer 13 in a state in which a color unevenness may not be highly visible, through the synergetic effects of combination with the above-mentioned first colored layer 20. The second colored layer 21 is provided above such a uniform underlayer, thus making it possible to prevent the above-mentioned second colored layer 21 from being subjected to influence from the color of the solar cell elements 11 and the color of the gap between them, and produce a desired color and represent a high grade designability in its entirety.

Each of the structural components of the solar cell module 100 will be described below.

### (Solar Cell Element)

As the solar cell elements 11 for the solar cell module 100 according to the embodiment of the present invention, the specifically limited element is not necessarily used, but the conventionally known elements may be selected appropriately and used. There may be sited, as such a solar cell element, for example, a monocrystal silicon solar cell element, a polycrystal silicon solar element, an amorphous silicon solar cell element, a compound semiconductor solar cell element, a dye-sensitized solar cell element, a quantum dot solar cell element, an organic thin film solar cell element, and the like.

Of these solar cell elements, the dye-sensitized solar cell element may especially be used suitably, since it has an advantage of a high power generation efficiency at a low luminance level in an indoor light such as a fluorescent light, or near the window and another advantage of a low manufacturing cost due to no need for a vacuum condition. In addition, the dye-sensitized solar cell element is preferably used, since it is used in a room as described above, and there is a demand for designability, and it is capable of providing technical effects of the present invention.

### (First Colored Layer)

The first colored layer 20 of the solar cell module 100 according to the embodiment of the present invention is subject to an adjustment process so that a difference in luminance between a color of a region above the solar cell element and a color of a region above a gap between adjacent solar cell elements, in an anterior view of a surface of the diffusion layer of the solar cell panel with the second colored layer removed, is up to 2.3. When providing the diffusion layer, it is significant to take particular note of the luminance of the color attributes and make a color adjustment, so as to make the color unevenness on the whole surface of the diffusion layer 13 not highly visible. The adjustment may be made so that the difference in luminance is up to 1.5 so as to make the color unevenness hot highly visible.

The value of the luminance may be determined based on Munsell color system as revised by the Optical Society of America, and may be measured with a spectrocolorimeter CM-700d (with a 2-degree of field of vision and a light source C) manufactured by KONICA MINOLTA.

In addition, the color of the first colored layer 20 may be adjusted so that the color difference ΔE calculated based on the following equation is up to 25.0, or particularly up to 15.0:

ΔE={(ΔL*)²+(Δa*)²+(Δb*)²}^{1/2}
wherein,
ΔE: color difference,
ΔL*, Δa*, Δb*: respective differences between values of L*, a*, b* of the color of the region above the solar cell element and values of L*, a*, b* of the color of the region above the gap between the adjacent solar cell elements.

L*, a*, b* may be determined based on the L*, a*, b* color system, which has been recommended by Commission Internationale de l'Eclairage (CIE) in 1976 and is prescribed in JIS Z8729, and may be measured with a spectrocolorimeter CM-700d (with a 10-degree of field of vision and a light source D65) manufactured by KONICA MINOLTA.

With respect to measurement of the value of the luminance and the values of L*, a*, b*, the second colored layer is removed from the solar cell module as completely manufactured, and then these values are measured from side of the light receiving surface of the solar cell module from which the second colored layer has been removed. If any other layers than the second colored layer exist between the diffusion layer and the second colored layer, or on the opposite side of the second colored layer to the diffusion layer, these layers are also removed to expose the surface of the diffusion layer, and then these values are measured.

With respect to a coloring measure, the specifically limited measure is not necessarily applied, but the conventionally known various kinds of coloring agents may be used to carry out an appropriate coloring process. More specifically, various kinds of dyes, or various kinds of pigments may be used or they may be used in combination. The coloring agent in the specifically limited form is not necessarily used, but there may be used the agent in the form of particles such as a spherical shape, an acicular shape, a scale shape, or the like. With respect to the size of the particle, there may be used the particle having the size of from about 1 nm to about 100 μm.

The first colored layer 20 may contain optional constituents, in addition to the above-mentioned coloring agent. There may optionally be added any additional constituents for forming the first colored layer 20, such as a resin as a binder, a solvent, a dispersant, or the like.

With respect to the thickness of the first colored layer 20, there is not necessarily applied the specifically limited thickness, and the first colored layer may appropriately be designed taking into consideration a place where the first colored layer 20 is to be formed, and the general structure of the solar cell module 100, and further a color shade to be expected through the first colored layer 20. In case where, for example, the first colored layer is formed as a solid layer on the back sheet 34 as in this embodiment of the present invention, it may have a thickness of from about 100 nm to about 10 μm.

There is no specific limitation also in forming the first colored layer 20. This layer may be formed by, for example, preparing an ink containing the coloring agent, and then applying the ink to the back sheet 34 by various application ways, or applying a printing process to the back sheet 34 based on various printing ways. Alternatively, a film or paper as colored may be placed between the back sheet 34 and the back surface side thermoplastic resin layer 31, so that they serve as the first colored layer.

The color of the first colored layer 20 may be adjusted so that each of the value of the luminance of the color of the region above the solar cell element and the value of the luminance of the color of the region above the gap between the adjacent solar cell elements, in an anterior view of the surface of the diffusion layer of the solar cell panel with the second colored layer removed, is within the range of from 5 to 10, in order to control the influence on the second colored layer. If the color of these regions is adjusted to be achromatic, it is possible to make the appearance of the whole surface of the diffusion layer 13 clear while or fine gray.

The color of the first colored layer 20 may be the same in color as a photoelectric conversion layer of the solar cell element, although not essential. The same color means that, when the solar cell element 11 and the first colored layer, which are placed adjacently to each other, are observed from a place just ten meters away from them, it is difficult to distinguish visually the gap between the solar cell element 11 and the first colored layer.

In the solar cell module 100 according to the present embodiment of the present invention, the first colored layer 20 is formed as the solid layer between the back sheet 34 and the back surface side thermoplastic resin layer 31. However, the present invention is not limited only to such an embodiment. For example, (1) the first colored layer 20 may be formed as a patterned layer covering the gap between the adjacent solar cell elements 11, between the back sheet 34 and the back surface side thermoplastic resin layer 31, (2) the coloring agent may be contained in the back surface side thermoplastic resin layer 31 so as to cause the back surface side thermoplastic resin layer 31 to function as the first colored layer, and further (3) the first colored layer 20 may be formed as a patterned layer covering the gap between the adjacent solar cell elements 11, between the light receiving surface side thermoplastic resin layer 30 and the polyethylene terephthalate resin layer 33.

### (Diffusion Layer)

With respect to the diffusion layer 13 of the solar cell module 100 according to this embodiment of the present invention, there is no other specific limitation as long as it is capable of diffusing an incident light. For example, conventionally known various kinds of diffusion layers may be selected appropriately and used.

The diffusion layer 13 may be used independently. However, it is preferable to use it in a state that voids 12 are provided below the diffusion layer, as shown in FIG. 1. The provision of such voids 12 below the diffusion layer 13 causes light incident on the solar cell module 100 to be diffused by the diffusion layer 13, and further causes it to be refracted and reflected on the interface between the voids 12 and the layer existing below them, e.g., the polyethylene terephthalate resin layer 33 as shown in FIG. 1, thus making it possible to enhance the luminance on the side of the light receiving surface of the solar cell module 100, through the synergetic effects of the diffusion layer 13 and the voids 12. If an attempt to provide the same luminance when using the voids 12 is made merely by the diffusion layer 13 without providing any voids 12, it is necessary to increase a degree of diffusion of the light by the diffusion layer, with the result an amount of light reaching the solar cell element 11 may be decreased, thus deteriorating the power generation efficiency.

When forming the voids 12, the void is not necessarily filled with a specific gas, but an existence of air suffices. The voids 12 are not necessarily formed as a continuous layer across the whole of the light receiving surface of the solar cell module 100. Accordingly, the voids may be formed by placing a material functioning as a spacer “S” between the diffusion layer 13 and the polyethylene terephthalate resin layer 33 provided blow the diffusion layer, as shown in FIG. 1. With respect to the depth of the void, there is not necessarily applied the specifically limited depth, and the voids may freely be designed within a scope for providing the above-described technical effects. It is preferable to limit it within the range of from about 1 nm to about 1000 μm, and further preferable to limit it within the range of from about 10 nm to about 100 μm.

With respect to a specific example of the diffusion layer 13, the diffusion layer 13 may be formed by preparing a film of for example polyester resin, polycarbonate resin or polyolefin resin, and providing this film with a concave-convex surface. The providing the film with such a concave-convex surface permits to bring the convex portions into direct contact with the layer existing below the diffusion layer 13, e.g., the polyethylene terephthalate resin layer as shown in FIG. 1, so as to cause them to serve as the spacer “S”, and to form the voids by the concave portions.

In case where such a film is used, the thickness of this film may appropriately be selected for the purpose of an intended use, but it may be determined as about 30 μm to about 300 μm. The concave-convex surface may be formed by adding polymeric or inorganic particles such as acrylic particles, polystyrene particles, silica particles, etc. to the film. Such particles may suitably be used in the form of a ball, a sphere or acicular shape. For example, these particles may be mixed with a binder resin in a solvent, and the resultant solution may be applied on the surface of the above-described film. The average particle size of these particles is preferably limited up to 30 μm. With the average particle size of over 30 μm, relatively coarse resin particle may easily come off, thus causing loss of the resin particles, and the appearance of the film as applied may tend to be inharmonic and non-uniform. There is not necessarily applied the specifically limited thickness of the part of the film, which contains these particles, but for example the thickness of about 1 μm to 15 μm is preferable. With respect to the back surface of the above-mentioned film, the back surface of the film preferably contains at least one kind of particles of acrylic particles, styrene particles, silicone particles, cross-linked polyacrylic acid ester particles and polyurethane particles, which are mainly in the form of a ball or a sphere. In such a case, the diameter of the particle is preferably within the range of from 1 μm to 60 μm, and further preferable within the range of from 5 μm to 20 μm. The thickness of the part of the film, which contains these particles on the back surface of the film, is preferable within the range of for example from 1 μm to 50 μm. As a binder to fix the particles on the back surface of the film, there may be used at least one kind selected from the group consisting of polyester resin, acrylic resin, silicone acrylic resin, fluoro resin or fluoro-acrylic resin, or such a resin to which a cross-linking resin having a curing function is added, or hardening resin such as polyurethane resin, epoxy resin, or the like.

When the above-described diffusion layer 13 is used, the particles are appropriately provided on the back surface side of this layer, so that these particles may function as the spacer “S” between the diffusion layer 13 and the layer existing below it, thus making it possible to form the voids 12 without providing a specific spacer “S”.

### (Second Colored Layer)

The second colored layer 21 of the solar cell module 100 according to the embodiment of the present invention is a layer to provide the solar cell module 100 with a desired designability. With respect to a coloring measure and a forming measure for this layer, the specifically limited measures are not necessarily applied, but it may freely be designed. In the solar cell module 100 according to the embodiment of the present invention, the area serving as the underlayer for the second colored layer 21 is kept free of color unevenness on its entirety through the synergetic effects of the first colored layer 20 and the diffusion layer 13, as well as the voids 12, as described above, and therefore a desired design can freely be made.

With respect to the constituents of such a second colored layer 21, the specifically limited constituents are not necessarily used, but various kinds of dyes or various kinds of pigments as the coloring agents may appropriately combined and used, in the same manner as the first colored layer 20 as described above. The second colored layer 21 may contain, in addition to the above-mentioned coloring agent, additional constituents such as a resin as a binder, a solvent, a dispersant, or the like for forming the second colored layer 21.

The use of the pigment as the coloring agent for the second colored layer permits to improve a weather resistance, thus being preferable. On the other hand, the use of the dye as the coloring agent for the second colored layer permits not only to produce a brilliant color so as to improve the designability, thus being preferable, but also to provide a bright color even in a small amount of the dye as applied to provide the designability, with the result that a high light transmission rate can be maintained even when forming the second colored layer as the solid layer, thus being preferable.

The second colored layer 21 is placed on the side of the light receiving surface of the solar cell module 100. It is therefore preferable that it has the highest transparency possible in light of the power generation efficiency of the solar cell element 11. An appropriate design for the transparency may be made taking into consideration a balance between the desired design and the desired power generation efficiency. An average transmissivity of the second colored layer 21, which depends on a desired design, is preferably determined for example as 20% or more, and preferably 50% or more, and further preferably 70% or more. The average transmissivity used in this specification means a visible light transmissivity on average on the surface of the second colored layer 21. The visible light transmissivity can be obtained by measuring a visible light wavelength range of from 380 nm to 750 nm with for example an SM color-computer SM-C (manufactured by Suga Test Instruments Co., Ltd.). It is preferable to use an average value of twelve samples as picked up arbitrarily in the light of accuracy improvement. If the second colored layer has on the surface portions that are quite different from each other in the visible light transmissivity, as in the case where the second colored layer has a motif or characters formed on it, the selection of the portions having a relatively larger occupied area and the obtainment of an average value of them suffice.

### (The Other Structural Components of the Solar Cell Module)

The solar cell module 100 according to the first embodiment of the present invention as shown in FIG. 1 is composed of the solar cell elements 11, the first colored layer 20, the diffusion layer 13, the void 12, the second colored layer 21, the light receiving surface side thermoplastic resin layer 30, the back surface side thermoplastic resin layer 31, the polyethylene terephthalate resin layer 33, the back sheet 34 and the sealing material 35. However, such a structure has merely been described as an exemplification, and the solar cell module of the present invention is not limited only to these structural components, and various modified components may be adopted. The materials for the components are not also limited only to them as described, and they may be selected from various kinds of materials.

Accordingly, for example, a glass substrate may be substituted for the polyethylene terephthalate resin layer 33. However, if the voids 12 are provided, it is preferable to provide a layer having a certain high degree of hardness in a place where the polyethylene terephthalate resin layer 33 has previously been provided, i.e., in a place where the layer faces the diffusion layer 13 through the voids 12. The reason for it will be described below. When manufacturing the solar cell module 100, the back sheet 34 and the sealing material 35 are thermal-fusion bonded to each other so that all the components are combined in a united body, as described above. Here, a pressure is applied to the diffusion layer 13 in the downward direction in the figure. If the layer, which is to be provided in a place where the polyethylene terephthalate resin layer 33 has previously been provided, is a layer formed of a soft material, the spacer “S” for forming the voids 12 may be buried into the layer of the soft material, resulting in no formation of the voids 12.

If a layer formed of any other material is substituted for the polyethylene terephthalate resin layer 33 in this light, it is preferable to provide a layer formed of material having the similar hardness to the polyethylene terephthalate resin or the larger hardness than it.

### Second Embodiment of the Present Invention

FIG. 2 is a schematic cross-sectional view of the solar cell module according to the second embodiment of the present invention.

In FIG. 2, the same structural components as those of the solar cell module 100 according to the first embodiment of the present invention as shown in FIG. 1 have the same reference numerals. The description of the same structural components as those of the solar cell module 100 according to the first embodiment of the present invention will be omitted.

### (Second Colored Layer)

The solar cell module 200 according to this embodiment of the present invention has a feature that the second colored layer is formed not as the so-called solid layer, but as a partially patterned layer, and such a patterned layer is provided in the form of dots, as shown in FIG. 2.

Providing the second colored layer 21 in the form of dots makes it possible to increase an amount of incident light on the solar cell element 11, thus being preferable.

In addition, providing the second colored layer 21 in the form of dots makes it possible to prevent a rapid voltage reduction, which may especially be caused at low average illumination intensity, thus being preferable. More specifically, the solar cell according to the present invention is assumed to be used under an indoor condition in which a high grade designability is required, and it is assumed that the illumination intensity is relatively low under the indoor condition. In such a place with the low illumination intensity, it is preferable to use the dye-sensitized solar cell element or the amorphous silicon solar cell element, as the solar cell element 11. Here, it is known that, when these solar cell elements 11 are used, a current value produced through a photoelectric conversion is proportional to intensity of light, and it is therefore possible to control this value by only the total light transmission rate on average on the light receiving surface of the solar cell element 11, but a voltage value is non-linear, and the reduction in illumination intensity to a predetermined value, for example, up to 1001× may cause a phenomenon of a rapid voltage reduction. It is possible to create, under such a situation, a partial area with a high illumination intensity, without reducing totally the illumination intensity on the light receiving surface of the solar cell element 11, by providing the colored layer 12 in the form of dots, thus preventing the rapid voltage reduction.

The second colored layer 21 of this embodiment of the present invention presents the form of dots. Therefore, It may also be considered that the above-mentioned second colored layer 21 has a low apparent concentration.

With respect to a measure to form the second colored layer 21 in the form of dots, the specifically limited measure is not necessarily applied, but there may be applied the measure, for example, an AM (Amplitude Modulation) Screening Method, an FM (Frequency Modulation) Screening Method, a Concentration Gradation Method, etc.

The AM Screening Method is a method to adjust an apparent concentration by controlling the size of the dots, and this method may be achieved by a gravure printing method, an AM screen-printing method, a fixed-head type ink jet printing method, etc. In general, the control of the size of the dots is easier than the control of the number of the dots, and this AM Screening Method permits to reduce lot-to-lot variation in power generation property of the products as the solar cell modules.

The FM Screening Method is a method to adjust an apparent concentration by controlling the number of the dots, and this method may be achieved by a FM screen-printing method, a fixed-head type ink jet printing method, etc. In general, it is possible to decrease the size of each of the dots by the FM Screening Method, in comparison with the AM Screening Method, and this FM Screening Method permits to adjust finely the concentration of the second colored layer 21.

The Concentration Gradation method is a method to adjust an apparent concentration by controlling a level of concentration of the dots, and this method may be achieved by a sublimation thermal transfer type printing method, an overprinting type ink jet printing method, etc. For example, by previously forming a colored layer, which is to become an underlayer, in the form of a solid layer in a place on which the second colored layer is to be formed, and then forming the second colored layer 21 in the form of dots on the above-mentioned solid colored layer, it is possible to provide a desired level of the concentration of the dots through the above-mentioned solid colored layer and the above-mentioned second colored layer 21. According to this method, it is also possible to reduce the thickness of the second colored layer 21, thus preventing the light from diffusing on the surface of the second colored layer 21.

The second colored layer 21 is not necessarily formed on the whole light receiving surface of the solar cell module 200, but it may be formed partially, for example in the form of motif or characters, in accordance with a desired design, as shown in FIG. 2.

### (Transparent Layer)

The solar cell module 200 according to this embodiment of the present invention is characterized in that a transparent layer 22 is provided between the diffusion layer 13 and the second colored layer 21. In the present invention, the diffusion layer 13 and the second colored layer are not necessarily provided so as to be directly adjacent to each other, and the other layer such as the transparent layer 22 may exist between them.

Providing the transparent layer 22 in this manner needs not provide the second colored layer 21 directly on the diffusion layer 13, thus increasing the degree of freedom for a measure to form the second colored layer 21 and permitting the formation of various kinds of the second colored layer 21 suited for a desired design. There may be adopted for example the following measure. A plurality of semi-finished uniform products each having the second colored layer 21 and the other structural components, which have previously been prepared, are prepared. There are prepared a laminated body in which the second colored layer 21 for constituting a certain design is provided on a protective layer described later and a laminated body in which the other second colored layer 21 for constituting the different design from the above-mentioned certain design is provided on a protective layer described later, respectively. Then, the laminated body, which has been selected in accordance with the desired design, is adhered on the semi-finished product through the transparent layer 22.

The material for the transparent layer 22 is not specifically limited, but the various kinds of transparent resin or glass may be selected appropriately and used.

### (Protective Layer)

The solar cell module 200 according to this embodiment of the present invention is characterized in that a protective layer 23 is provided on the second colored layer 21.

Providing the protective layer 23 in this manner can prevent the second colored layer from being deteriorated or peeled off, thus protecting the second colored layer 21. If the protective layer 23 is provided, even when there occurs a phenomenon that the coloring agent contained in the second layer 21 is floated on the surface of the second colored layer 21 due to a thermal diffusion, i.e., a so-called bleed out, the protective layer 23 as provided can trap the coloring agent as bled out, thus preventing the surface of the solar cell module 200 from being spotted by the coloring agent.

The material for the protective layer 23 is not specifically limited, but the various kinds of transparent resin or glass may be selected appropriately and used. In case where the second colored layer 21 contains the dye, the addition of a weather resistance improving agent such as an ultraviolet rays absorbing agent, an oxidation inhibitor, etc. to the protective layer 23 makes it possible to protect the dye from sunlight.

### Third Embodiment of the Present Invention

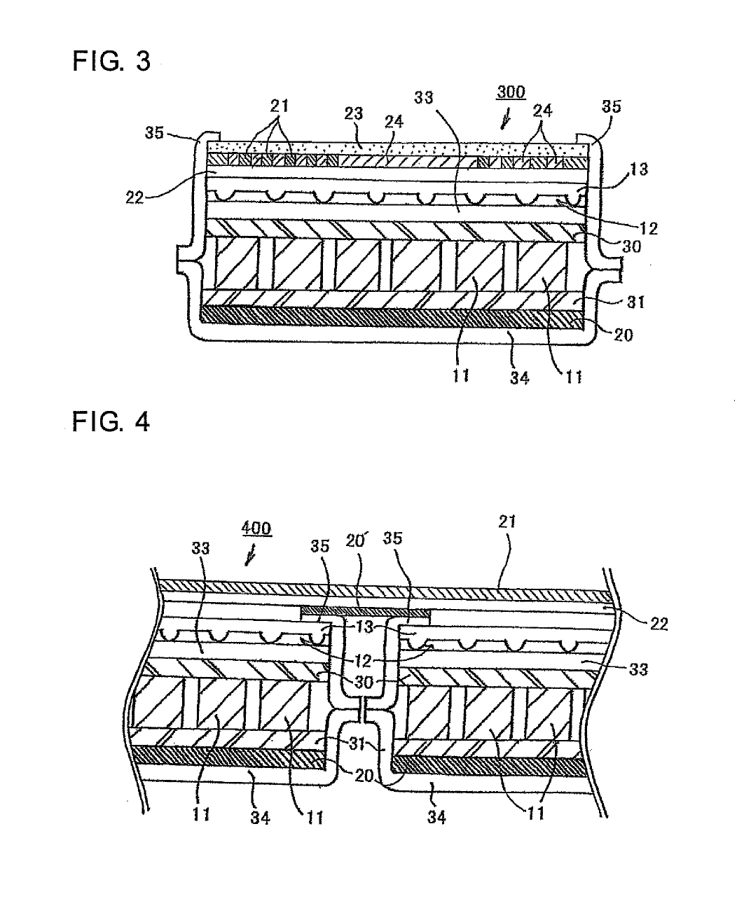

FIG. 3 is a schematic cross-sectional view of the solar cell module according to the third embodiment of the present invention.

In FIG. 3, the same structural components as those of the solar cell modules 100, 200 according to the first and second embodiments of the present invention as shown in FIG. 2 have the same reference numerals. The description of the same structural components as those of the solar cell modules 100, 200 according to the first and second embodiments of the present invention will be omitted.

### (Second Transparent Layer)

The solar cell module 300 according to this embodiment of the present invention is characterized in that the second colored layer is composed of a plurality of colored sections 21, 21 formed on the same plane, so as to provide a patterned layer, and the second transparent layer is composed of a plurality of transparent sections 24 provided between the adjacent colored sections 21, 21 of the second colored layer.

The transparent layer is not necessarily formed in a single layer, but may be provided appropriately in required areas. The provision of the second transparent layer 24 between the second colored layers 21 permits to combine these two layers into a united layer. More specifically, it is possible to utilize, in a single layer, the area, which is colored by the coloring agent, as the second colored layer 21, and utilize the area, which is not colored by the coloring agent, as the second transparent layer 24.

### Fourth Embodiment of the Present Invention

FIG. 4 is a schematic cross-sectional view of the solar cell panel according to the fourth embodiment of the present invention.

In FIG. 4, the same structural components as those of the solar cell modules 100, 200 according to the first to third embodiments of the present invention as shown in FIGS. 1 to 3 have the same reference numerals. The description of the same structural components as those of the solar cell modules 100, 200, 300 according to the first to third embodiments of the present invention will be omitted.

The solar cell panel 400 according to this embodiment of the present invention is composed of a plurality of solar cell modules. More specifically, the solar cell module includes two or more solar cell elements 11, 11 . . . placed at intervals; a light receiving surface side thermoplastic resin layer 30 and a back surface side thermoplastic resin layer 31 between which these solar cell elements 11, 11 . . . are held; a polyethylene terephthalate resin layer placed on the light receiving surface side thermoplastic resin layer 30; a back sheet 34 placed on the back surface of the solar cell module 100; and a sealing material 35 placed at the edge of the light receiving surface of the solar cell module 100, a first colored layer 20 provided between the back sheet 34 and the back surface side thermoplastic resin layer 31; and further a diffusion layer 13 provided on the side of the light receiving surface, which are combined into a united body by thermal-fusion bonding the above-mentioned back sheet 34 and the sealing material 35, and this embodiment is characterized in that the above-mentioned first colored layer 20′ is also provided between the adjacent solar cell modules, in a state where the solar cell modules each being combined into the united body are placed in parallel to each other, and the transparent layer 22 and the second colored layer 21 are placed across the whole surface of the light receiving surfaces of the solar cell modules.

The technical idea of the solar cell module according to the present invention may be applied to the solar cell panel 400, which is composed of a plurality of solar cell modules, in this manner. More specifically, the single solar cell module and the single second colored layer 21 are not necessarily provided in an one-to-one relationship, as in the embodiment of the present invention as described above. The single transparent layer and the single second colored layer may be provided for a plurality of solar cell modules. Such an embodiment permits to utilize the plurality of solar cell modules as a single panel, thus being advantageous when placing them in an large area.

In addition, providing the first colored layer 20′ also between the adjacent solar cell modules of which the solar cell panel is composed makes it possible to control the color unevenness caused between the adjacent solar cell modules, thus providing a high grade designability. The first colored layer 20′ is provided between the sealing material 35 and the transparent layer 22 in FIG. 4. However, there is no positional limitation, and it may be provided in any place between the adjacent solar cell modules, when viewing the solar cell panel from the light receiving surface side. It may be provided in a place between the adjacent solar cell modules for example on the rear surface side of the solar cell modules.

In this embodiment of the present invention, the transparent layer 22 and the second colored layer 21 may be formed integrally with each other, and such an integral body may be peeled off from the sealing material 35. This makes it possible to make the design presented by the second colored layer 21 changeable, thus changing the design with a lapse of time for example in a manner of a poster.

### Fifth Embodiment of the Present Invention

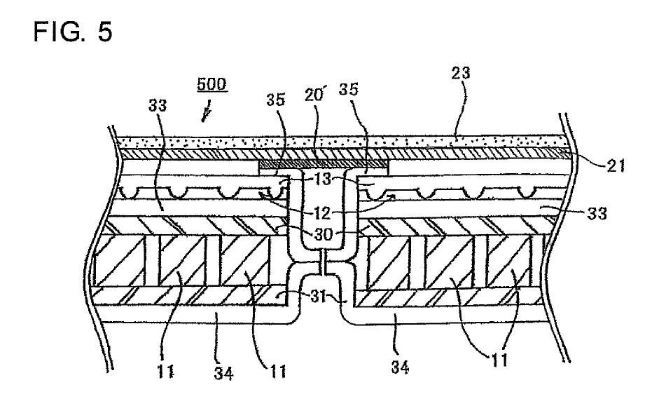

FIG. 5 is a schematic cross-sectional view of the solar cell panel according to the fifth embodiment of the present invention.

Also in FIG. 5, the same structural components as those of the embodiments of the present invention as shown in FIGS. 1 to 3 have the same reference numerals in the same manner as the solar cell panel 400 according to the fourth embodiment of the present invention, and the description of them will be omitted.

The solar cell panel 500 according to this embodiment of the present invention differs from the solar cell panel 400 according to the fourth embodiment of the present invention as shown in FIG. 4 in that each of the solar cell modules of which the solar cell module is composed does not have the first colored layer.

There is a case where the gap between the adjacent solar cell elements 11 of which the solar cell module of the solar cell panel 500 is not be highly visible, but the gap between the adjacent solar cell modules is visible. In such a case, the first colored layer 20′ may be provided only between the adjacent solar cell modules, thus improving the designability of the whole solar cell panel 500.

In addition, the solar cell panel 500 according to this embodiment of the present invention differs from the solar cell panel 400 according to the fourth embodiment of the present invention as shown in FIG. 4 in that the second colored layer 21 and the protective layer 23 are provided across the whole light receiving surfaces of the solar cell modules of which the solar cell panel is composed, and in that the transparent layer 22 is not provided.

The transparent layer 22 is an optional layer and is not necessarily provided. The second colored layer 21 can be protected by providing the protective layer 23.

### The Other Embodiment 1 of the Present Invention

With respect to the fourth embodiment of the present invention, there is described, “the transparent layer 22 and the second colored layer 21 may be formed integrally with each other, and such an integral body may be peeled off from the sealing material 35”. However, in any one of the first to fifth embodiments of the present invention as described above, the diffusion layer 13 may included in addition to the transparent layer 22 and the second colored layer 21 so as to be peeled off. This makes it possible to make the design changeable, thus changing the design when the second colored layer is deteriorated, in the same manner as the fourth embodiment of the present invention.

### The Other Embodiment 2 of the Present Invention

The second colored layer 21 may be provided in a position so as to overlap with the solar cell element 11, and the dye may be used in a coloring process of the second colored layer 21 and the color of it may be the same as that of the solar cell element 11 although it is not shown. This makes it possible to overlap the solar cell element 11 and the second colored layer 21 both having the same color with each other, thus making this color brilliant. In addition, the dye is used in the coloring process of the second colored layer 21, and a light having the other color than the same color may be transmissive, thus leading to a small impact on the power generation efficiency.

### EXAMPLES

### Example No. 1 of the Present Invention

The solar cell modules according to Example No. 1 of the present invention were prepared in the manner as described below.

### (Preparation of Solar Cell Element and Solar Cell Module)

A paste, which was been prepared by mixing, in ethanol, ethyl cellulose of 0.5% (STD-100: Nisshin Kasei Co. Ltd.) with titanium oxide particle (P25: Nippon Aerosil Co., Ltd.) was applied to a Ti foil (Takeuchi Metallic Foil Co. Ltd.) as an electrode substrate having the thickness of 50 μm, and then dried. Then, the resultant was subjected to a roller-pressing treatment utilizing a small roller-pressing machine at a pressure of 0.5 t/cm and at a speed of 1 m/minute. Then, the resultant was calcined at a temperature of 500 for half an hour so as to prepare a porous layer-formation layer having a thickness of 5 μm.

Then, there was prepared a dye-sensitized agent solution in which D358 dye (Mitsubishi Paper Mills Limited) was dissolved in an acetonitrile/t-butanol=1/1 solution in an amount of 0.5 mM. The above-mentioned porous layer-formation layer was immersed into this dye-sensitized agent solution for three hours, and then dried, to prepare an oxide semiconductor electrode substrate having a size of 10 cm×4 cm (a film-formed area: 9.5 cm×4 cm).

Then, there was prepared an electrolyte in which hexyl methyl imidazolum iodide (Toyama Pure Chemical Industries, LTD.) of 6 mol/l and I₂ (Merck Ltd.) of 0.6 mol/l were dissolved into hexyl methyl imidazolum tetracyano borat (Merck Ltd.). Then, there was prepared a resin solution in which 0.5 wt. % cationized cellulose (QH-400: Daicel Fine Chem Ltd.) in an amount of 10 wt. % was dissolved into ethanol, and the resultant resin solution was mixed to the above-mentioned electrolyte at the rate of the electrolyte:the resin solution=1:6 (by weight) to prepare a resin electrolyte solution. The resin electrolyte solution was applied to the above-mentioned oxide semiconductor electrode substrate with the use of Mayer Rod, and then it was heated at a temperature of 120 ° C. for 10 minutes.

Then, a counter-electrode having a size of 10 cm×4 cm was prepared by forming a film of Pt, so as to achieve transmissivity of 80%, on a film of tin-doped indium oxide of a polyethylenenaphthalate substrate with a film of tin-doped indium oxide of 30 Ω/sq.

Then, the oxide semiconductor electrode substrate with electrolyte and the counter-electrode, as prepared described above, were bonded together in a state in which they were displaced from each other by 5 mm both in horizontal and vertical directions, and the electrode of one element was connected to the counter-electrode of the other element by a metallic tape. The solar cell element was prepared in this manner.

Then, two solar cell elements were aligned at an interval of 0.8 cm, and there were placed, on their light receiving surface side, the light receiving surface side thermoplastic resin layer (having a size of 11 cm×10 cm (an ethylene-vinyl acetate copolymer resin film having the thickness of 400 μm: manufactured by Tamapoly Co. Ltd.)), the polyethylene terephthalate resin layer (having a size of 10 cm×9 cm (Lumirror T60: manufactured by Toray Industries, Inc.)), and a wood-effect wallpaper as the second colored layer (having a size of 10 cm×9 cm) having an average transmissivity of 77%, and on the back surface side, the light receiving surface side thermoplastic resin layer (having a size of 11 cm×10 cm (an ethylene-vinyl acetate copolymer resin film having the thickness of 400 μm: manufactured by Tamapoly Co. Ltd.)), and a back sheet as the first colored layer (having a size of 12 cm×11 cm) (Alumilamizip: As One Corporation) laminated with a color adjusting layer A (having a size of 11 cm×10 cm). Then, the outer periphery (non-power generation section) of the element was covered with a sealing material (Alumilamizip: As One Corporation), which can be thermal-laminated and has a barrier property, and this was subjected to a thermal-lamination process at a temperature of 120 degree, thus preparing the solar cell module according to Example No. 1 of the present invention. There were the convex portions on the side of the surface of the diffusion layer, which come into contact with the polyethylene terephthalate resin layer, and the diffusion layer only at the periphery of the element was subjected to the thermal-lamination process, with the result that the voids were provided between the diffusion layer and the polyethylene terephthalate resin layer.

### Measurement in Example No. 1 of the Present Invention

There was made a measurement of the cell performance and a design of the light receiving surface of the solar cell module of Example No. 1 of the present invention. Measurement results were as follows:
Photoelectric conversion efficiency: 1.7%
Output performance: Open voltage of 1.5 V
Design of light receiving surface: Clear wood-effect appearance as displayed

The color based on Munsell color system was measured with the use of the spectrocolorimeter CM-700d (with a 2-degree of field of vision and a light source C) manufactured by KONICA MINOLTA, and the color based on the L*, a*, b* color system was measured with the use of the spectrocolorimeter CM-700d (with a 10-degree of field of vision and a light source D61) manufactured by KONICA MINOLTA.

When the measurement was made before installation, the color of the color adjusting layer A was 1.0PB 1.04/0.28 based on Munsell color system, and L=11.04, a=−0.44, b=−1.48 based on the L*, a*, b* color system.

When the measurement was made after removing the wood-effect wallpaper from the solar cell module of Example No. 1 of the present invention, the color of the region above the solar cell element on the surface of the diffusion layer was 5.9PB 6.65/1.5 based on Munsell color system, and L=68.04, a=−0.1, b=−2.12 based on the L*, a*, b* color system.

When the measurement was made after removing the wood-effect wallpaper from the solar cell module of Example No. 1 of the present invention, the color of the region above the gap between the adjacent solar cell elements on the surface of the diffusion layer was 5.8PB 5.24/1.14 based on Munsell color system, and L=54.19, a=−0.06, b=−4.23 based on the L*, a*, b* color system.

Table 1 indicated later includes the following particulars: (1) difference between the luminance of the color of the region above the solar cell element and the luminance of the color of the region above the gap between the adjacent solar cell elements, (2) the color difference ΔE between the color of the region above the solar cell element and the color of the region above the gap between the adjacent solar cell elements, and (3) assessment results on visibility of the solar cell module from which the wood-effect wallpaper has been removed, when visually observing the light receiving surface of the solar cell module in an anterior view, from a place just ten meters from it, so that the direction of eyes was almost horizontal. Here, the assessment criteria for item (3) above were as follows:
Excellent: The region above the gap between the adjacent solar cell elements and the region above the solar cell element being observed evenly.
Good: The region above the gap between the adjacent solar cell elements and the region above the solar cell element being observed almost evenly.
Not Good: The region above the gap between the adjacent solar cell elements and the region above the solar cell element being observed separately.

### Example No. 2 of the Present Invention

There were prepared the solar cell modules according to Example No. 2 of the present invention, which were the same as the solar cell modules according to Example No. 1 of the present invention, except that a color adjusting layer B was formed as the first colored layer. The color of the color adjusting layer B was 2.7PB 0.53/0.28 based on Munsell color system, and L=41.82, a=−0.53, b=−1.35 based on the L*, a*, b* color system. The color of the region above the gap between the adjacent solar cell elements on the surface of the diffusion layer was 5.7PB 6.37/0.74 based on Munsell color system, and L=65.45, a=−0.20, b=−2.33 based on the L*, a*, b* color system.

### Example No. 3 of the Present Invention

There were prepared the solar cell modules according to Example No. 3 of the present invention, which were the same as the solar cell modules according to Example No. 1 of the present invention, except that a color adjusting layer C was formed as the first colored layer. The color of the color adjusting layer C was 1.8G 7.23/2.07 based on Munsell color system, and L=73.83, a=−10.06, b=7.38 based on the L*, a*, b* color system. The color of the region above the gap between the adjacent solar cell elements on the surface of the diffusion layer was 1.8G 7.23/2.07 based on Munsell color system, and L=73.83, a=−10.06, b=7.38 based on the L*, a*, b* color system.

### Example No. 4 of the Present Invention

There were prepared the solar cell modules according to Example No. 4 of the present invention, which were the same as the solar cell modules according to Example No. 1 of the present invention, except that a color adjusting layer D was formed as the first colored layer. The color of the color adjusting layer D was 4.3R 2.33/5.83 based on Munsell color system, and L=23.90, a=29.78, b=9.39 based on the L*, a*, b* color system. The color of the region above the gap between the adjacent solar cell elements on the surface of the diffusion layer was 3.7R 4.51/1.23 based on Munsell color system, and L=54.69, a=9.71, b=4.85 based on the L*, a*, b* color system.

### Example No. 1 for Comparison

The solar cell modules according to Example No. 1 for Comparison were prepared under the same conditions except that the first colored layer of the Example No. 1 of the present invention was not provided.

### Measurement in Example No. 1 for Comparison

There was made a measurement of the cell performance and a design of the light receiving surface of the solar cell module of Example No. 1 for Comparison. Measurement results were as follows:
Photoelectric conversion efficiency: 1.7%
Output performance: Open voltage of 1.5 V
Design of light receiving surface: A wispy white striped pattern being observed together with the wood-effect pattern, result in difficulty in observing a clear wood-effect appearance.

When the measurement was made after removing the wood-effect wallpaper from the solar cell module of Example No. 1 for Comparison, the color of the region above the gap between the adjacent solar cell elements on the surface of the diffusion layer was 6.5GY 9.81/0.09 based on Munsell color system, and L=89.22, a=−0.38, b=0.67 based on the L*, a*, b* color system.

TABLE 1

| | (1) Difference | (2) Difference in | |
|---|---|---|---|
| | in luminance | color | (3) Visibility |
| Example No. 1 of the | 1.41 | 14.01 | Excellent |
| present invention | | | |
| Example No. 2 of the | 0.28 | 2.60 | Excellent |
| present invention | | | |
| Example No. 3 of the | 0.58 | 14.93 | Excellent |
| present invention | | | |
| Example No. 4 of the | 2.14 | 22.14 | Good |
| present invention | | | |
| Example No. 1 for | 3.16 | 21.36 | Not Good |
| Comparison | | | |

### (Assessment)

It was revealed from Table 1 that, when the difference between the luminance of the color of the region above the solar cell element and the luminance of the color of the region above the gap between the adjacent solar cell elements was up to 2.3, the region above the gap between the adjacent solar cell elements and the region above the solar cell element were observed evenly or almost evenly. In addition, it was revealed from the results of the measurements of the solar cell modules according to Example No. 1 of the present invention and Example No. 1 for Comparison that the solar cell module according to the present invention could provide a higher grade designability than the conventional solar cell module without decreasing the photoelectric conversion efficiency.

### DESCRIPTION OF REFERENCE NUMERALS

100, 200, 300 - - - solar cell module
400, 400 - - - solar cell panel
11 - - - solar cell element
12 - - - void
13 - - - diffusion layer
20, 20′ - - - first colored layer
21 - - - second colored layer
22 - - - transparent layer
30 - - - light receiving surface side thermoplastic resin layer
31 - - - back surface side thermoplastic resin layer
33 - - - polyethylene terephthalate resin layer
34 - - - back sheet
35 - - - sealing material

What is claimed is:

1. A solar cell module comprising:
two or more solar cell elements provided at intervals;
a first colored layer provided between adjacent solar cell elements; and
a diffusion layer and a second colored layer provided, on a side of a light receiving surface of said solar cell module, directly or through another layer in this order from the solar cell element side,
wherein:
a difference in luminance between a color of a region above said solar cell element and a color of a region above a gap between adjacent solar cell elements, in an anterior view of a surface of the diffusion layer of the solar cell module with said second colored layer removed, is up to 2.3.

2. The solar cell module as claimed in claim 1, wherein:
said second colored layer is provided in a form of dots.

3. The solar cell module as claimed in claim 1, further comprising:
a transparent layer provided between said diffusion layer and said second colored layer.

4. The solar cell module as claimed in claim 2, further comprising:
a transparent layer provided between said diffusion layer and said second colored layer.

5. The solar cell module as claimed in claim 1, wherein:
a color difference ΔE between the color of the region above said solar cell element and the color of the region above the gap between the adjacent solar cell elements, in an anterior view of the surface of the diffusion layer of the solar cell module with said second colored layer removed, is up to 15.0.

6. The solar cell module as claimed in claim 2, wherein:
a color difference ΔE between the color of the region above said solar cell element and the color of the region above the gap between the adjacent solar cell elements, in an anterior view of the surface of the diffusion layer of the solar cell module with said second colored layer removed, is up to 15.0.

7. The solar cell module as claimed in claim 3, wherein:
a color difference ΔE between the color of the region above said solar cell element and the color of the region above the gap between the adjacent solar cell elements, in an anterior view of the surface of the diffusion layer of the solar cell module with said second colored layer removed, is up to 15.0.

8. The solar cell module as claimed in claim 4, wherein:
a color difference ΔE between the color of the region above said solar cell element and the color of the region above the gap between the adjacent solar cell elements, in an anterior view of the surface of the diffusion layer of the solar cell module with said second colored layer removed, is up to 15.0.

9. The solar cell module as claimed in claim 1, further comprising:
a protective layer provided on said second colored layer.

10. The solar cell module as claimed in claim 2, further comprising:
a protective layer provided on said second colored layer.

11. The solar cell module as claimed in claim 3, further comprising:
a protective layer provided on said second colored layer.

12. The solar cell module as claimed in claim 4, further comprising:
a protective layer provided on said second colored layer.

13. The solar cell module as claimed in claim 5, further comprising:
a protective layer provided on said second colored layer.

14. The solar cell module as claimed in claim 6, further comprising:
a protective layer provided on said second colored layer.

15. The solar cell module as claimed in claim 7, further comprising:
a protective layer provided on said second colored layer.

16. The solar cell module as claimed in claim 8, further comprising:
a protective layer provided on said second colored layer.

17. A solar cell panel comprising:
two or more solar cell modules provided at intervals, each of said solar cell modules comprising two or more solar cell elements provided at intervals;
a first colored layer provided between adjacent solar cell elements of the solar cell module and between adjacent solar cell modules; and
a diffusion layer and a second colored layer provided, on a side of a light receiving surface of said solar cell panel, directly or through another layer in this order from the solar cell element side,
wherein:
a difference in luminance between a color of a region above said solar cell element and a color of regions above a gap between the adjacent solar cell elements and a gap between the adjacent solar cell modules, in an anterior view of a surface of the diffusion layer of the solar cell panel with said second colored layer removed, is up to 2.3.

18. A solar cell panel comprising:
two or more solar cell modules provided at intervals, each of said solar cell modules comprising two or more solar cell elements;
a first colored layer provided between adjacent solar cell modules; and
a diffusion layer and a second colored layer provided, on a side of a light receiving surface of said solar cell panel, directly or through another layer in this order from the solar cell element side,
wherein:
a difference in luminance between a color of a region above said solar cell element and a color of a region above a gap between the adjacent solar cell modules, in an anterior view of a surface of the diffusion layer of the solar cell panel with said second colored layer removed, is up to 2.3.
